(19) United States
(12) Patent Application Publication
(10) Pub. No.: US 2021/0028539 A1
(43) Pub. Date: Jan. 28, 2021

(54) Enhanced Antenna Module with Flexible Portion

(71) Applicant: QUALCOMM Incorporated, San Diego, CA (US)

(72) Inventors: Hong Bok WE, San Diego, CA (US); Jaehyun Yeon, San Diego, CA (US); Suhyung Hwang, Rancho Mission Viejo, CA (US); Darryl Sheldon Jessie, San Diego, CA (US)

(21) Appl. No.: 16/520,140

(22) Filed: Jul. 23, 2019

(51) Int. Cl. H01Q 3/08; H01Q 3/01; H01Q 1/08

(52) U.S. Cl. CPC H01Q 3/08; H01Q 1/085; H01Q 3/01

(57) ABSTRACT

Methods and apparatuses for enhancing antenna modules with flexible portion are presented. An apparatus includes an antenna module having a first portion, a first antenna on the first portion, a second portion, a second antenna on the second portion, and a flexible portion physically connecting the first portion and the second portion. The flexible portion is arrangeable such that the first antenna and the second antenna are oriented to receive radio frequency signals from different directions or to transmit the radio frequency signals to different directions. At least one radio frequency integrated circuit is on the first portion. The first antenna and the second antenna, via the flexible portion, share the radio frequency integrated circuit for radio frequency signal transmission or reception.

### BACKGROUND

### Field

The present disclosure relates generally to methods and apparatuses having enhanced antenna module and more particularly, to enhanced antenna modules with a flexible portion.

### Background

As demands for functions and services over wireless communication network grow, demands on antenna modules, incorporated within apparatuses, to communicate over such networks increase accordingly. Such antenna modules may be configured to operate using different protocols, such as cellular protocols (5G, LTE, etc.), Wi-Fi, and Bluetooth at different frequency bands. The antenna modules may further be part of a multiple-input and multiple-output (MIMO) system. The demands may call for the antenna modules to communicate using more protocols, more frequency bands, and/or higher speeds. As a result, demands for the antenna modules to improve performance grow.

### SUMMARY

This summary identifies features of some example aspects and is not an exclusive or exhaustive description of the disclosed subject matter. Additional features and aspects are described and will become apparent to persons skilled in the art upon reading the following detailed description and viewing the drawings that form a part thereof.

An apparatus in accordance with at least one embodiment includes an antenna module with flexible portion. The apparatus includes an antenna module having a first portion, a first antenna on the first portion, a second portion, a second antenna on the second portion, and a flexible portion physically connecting the first portion and the second portion. The flexible portion is arrangeable such that the first antenna and the second antenna are oriented to receive radio frequency signals from different directions or to transmit the radio frequency signals to different directions. At least one radio frequency integrated circuit is on the first portion. The first antenna and the second antenna, via the flexible portion, share the radio frequency integrated circuit for radio frequency signal transmission or reception.

A method to form an apparatus incorporating an antenna module with a flexible portion, in accordance with at least one embodiment, includes forming a plurality of layers as an integrated structure, the plurality of layers including a flexible layer and a signal routing layer. The method further includes cutting a portion of the plurality of layers to form a flexible portion.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 illustrates components of an apparatus having an antenna module, in accordance with certain aspects of the present disclosure.

FIG. 2A illustrates physical representation of the antenna module of FIG. 1 arranged in a first position, in accordance with certain aspects of the present disclosure.

FIG. 2B illustrates physical representation of the antenna module of FIG. 1 arranged in a second position, in accordance with certain aspects of the present disclosure.

FIG. 3 illustrates a perspective view of the apparatus incorporating the antenna module of FIG. 1, in accordance with certain aspects of the present disclosure

FIGS. 4A and 4B illustrate a method to manufacture the apparatus incorporating the antenna module of FIG. 1, in accordance with certain aspects of the present disclosure.

FIG. 5 illustrates stages of the method of FIGS. 4A and 4B, in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for providing a thorough understanding of various concepts. However, it will be apparent to those skilled in the art that these concepts may be practiced without these specific details. In some instances, well known structures and components are shown in block diagram form to avoid obscuring such concepts.

As used herein, the term “coupled to” in the various tenses of the verb “couple” may mean that element A is directly connected to element B or that other elements may be connected between elements A and B (i.e., that element A is indirectly connected with element B), to operate certain intended functions. In the case of electrical components, the term “coupled to” may also be used herein to mean that a wire, trace, or other electrically conductive material is used to electrically connect elements A and B (and any components electrically connected therebetween). In some examples, the term “coupled to” mean a transfer of electrical energy between elements A and B, to operate certain intended functions.

In some examples, the term “electrically connected” mean having an electric current or configurable to having an electric current flowing between the elements A and B. For example, the elements A and B may be connected via resistors, transistors, or an inductor, in addition to a wire, trace, or other electrically conductive material and components. Furthermore, for radio frequency functions, the elements A and B may be “electrically connected” via a capacitor or other components.

The terms “first,” “second,” “third,” etc. are employed for ease of reference and may not carry substantive meanings. Likewise, names for components/modules may be adopted for ease of reference and might not limit scopes of the components/modules. The term “direction,” when referred to radio frequency signals, may refer to a direction the radio frequency signals travels. The term “orthogonal” would be a degree understood by persons of ordinary skill in the arts to be suitable for wireless communication. Modules and components presented in the disclosure may be implemented in hardware, software, or a combination of hardware and software.

The term “bus system” may provide that elements coupled to the “bus system” may exchange information therebetween, directly or indirectly. In such fashion, the “bus system” may encompass multiple physical connections as well as intervening stages such as buffers, latches, registers, etc.

The terms “disposed on,” “on” (when used to described physical relationship), “affixed on” may indicate the elements being physically connected, either directly (no intervening elements therebetween or the elements touching each other) or indirectly (at least one additional element therebetween). Thus, in some examples, “disposed on” may indicate directly disposed on; “on” may indicate directly on; and/or “affixed” may indicate directly affixed.

As demands for communication grow, antenna modules are called upon to include multiple antennas. For example, radio frequency (RF) in 5G communications may reflect from walls or other surfaces and travel in different directions. Accordingly, antennas of an antenna module may preferable be able to receive radio frequency (RF) signals from multiple, different directions, such as from orthogonal directions. Presented herein are enhanced antenna modules with flexible portions that are arrangeable such that antennas on the antenna modules are oriented to receive RF signals from different directions (e.g., orthogonal) and/or to transmit RF signals in different (e.g., orthogonal) directions. In such fashion, coverages RF signal reception and transmission are improved.

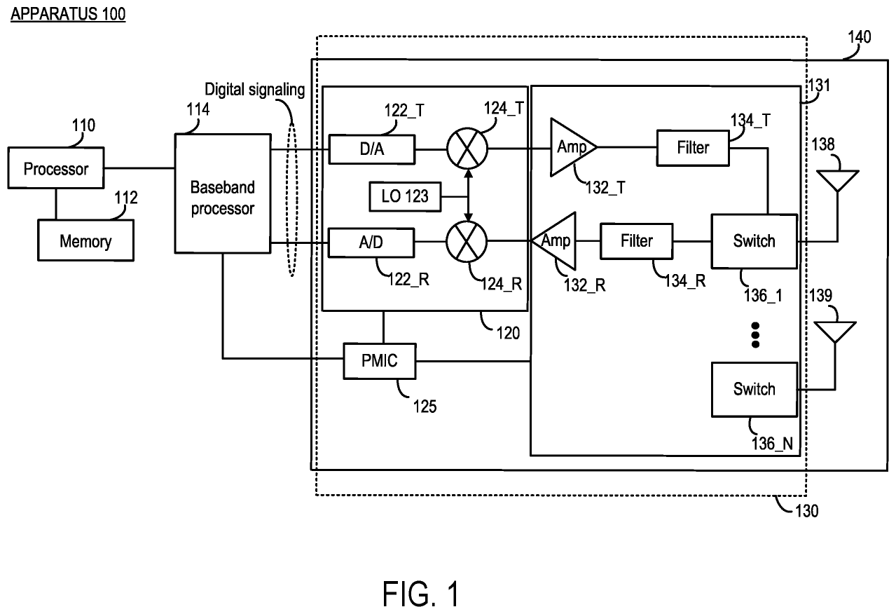

FIG. 1 illustrates components of an apparatus 100 having an antenna module 140, in accordance with certain aspects of the present disclosure. The apparatus 100 may, for example, be one of a computing system (e.g., servers, datacenters, desktop computers), mobile computing device (e.g., laptops, cell phones, vehicles, etc.), Internet of Things device, virtual reality system, or augmented reality system and may be configured to function as an user equipment or a base station. FIG. 1 illustrates the apparatus 100 incorporating at least one processor 110, a memory 112, a baseband processor 114, and an antenna module 140. The baseband processor 114 is coupled to the memory 112 and may be configured to perform a computing function (e.g., graphic, displaying function, or sensing, etc., for the computing system, mobile computing device, Internet of Things device, virtual reality system, or augmented reality system) with the memory 112. For example, the memory 112 may store an instruction or data for the computing function.

The at least one processor 110 is coupled to the baseband processor 114 and to the antenna module 140 to perform, for example, wireless communications. The baseband processor 114 is coupled to the antenna module 140 and may be configured to operate RF communicating functions via wireless communication networks. For example, the baseband processor 114 may be configured to formulate logic layers and physical layers signaling based on protocols of the wireless communication networks (e.g., 5G, LTE, Wi-Fi, Bluetooth, etc.) in digital domain. The baseband processor 114 may be configured to output to (or to input from) the antenna module 140 for transmission (or receiving) of RF signaling via the antenna module 140.

The antenna module 140 includes a first antenna 138 and a second antenna 139, which provide means to transmit or to receive RF signals for the wireless communication networks. The first antenna 138 and the second antenna 139 may be, for example, patch antennas. The antenna module 140 may be configured to include at least one RF integrated circuit (RFIC) 130 functionally coupling the baseband processor 114 to the first antenna 138 and the second antenna 139 to facilitate RF communications. For example, the at least one RFIC 130 may include one or more of a transceiver 120, a power management integrated circuit (PMIC) 125, an RF front-end 131, and/or an envelope-tracking circuit (not shown), etc. FIG. 1 illustrates that the antenna module 140 (e.g., the RFIC 130) includes, the transceiver 120, the PMIC 125, and the RF front-end 131. In addition, the antenna module 140 may further include passive components (such as inductors and capacitors; not shown) that function with the at least one RFIC 130 to perform RF communications between the baseband processor 114 and the first antenna 138 (or the second antenna 139).

The PMIC 125 may be configured to provide power to the transceiver 120 (and/or the RF front-end 131). The transceiver 120 may be configured to convert digital signaling from the baseband processor 114 to RF signaling in a carrier frequency for transmission by the first antenna 138 (or the second antenna 139) and/or, to convert RF signals at the carrier frequency received from the first antenna 138 (or the second antenna 139) into digital signaling for the baseband processor 114. FIG. 1 illustrates that the transceiver 120 includes an analog-to-digital converter (ADC) 122_R, a digital-to-analog converter (DAC) 122_T, a local oscillator 123, and mixers 124_T and 124_R. The ADC 122_R and the DAC 122_T may convert signaling between analog and digital domains. The local oscillator 123 may generate a carrier-frequency reference signal, and the mixers 124_T and 124_R may mix the carrier-frequency reference signal with signals received from or to be transmitted by first antenna 138 or by the second antenna 139, via the RF front-end 131.

The RF front-end 131 may be configured to select and to adjust RF signals for transmission or RF signals received by the first antenna 138 (or the second antenna 139). FIG. 1 illustrates that the RF front-end 131 includes amplifiers 132_T and 132_R, filters 134_T and 134_R, and switches 136-1 to 136-N. The amplifiers 132_T and 132_R may increase amplitudes of signaling. The filters 134_T and 134_R may remove unwanted signaling (e.g., unwanted frequency bands or interferences). The switches 128-1 to 128-N (which in some examples, may include duplexers) may switch between providing signals to and receiving signals from the first antenna 138 (or the second antenna 139), between signaling paths in a multiple-input and multiple-output system, between different wireless communication protocols, or between different frequency bands.

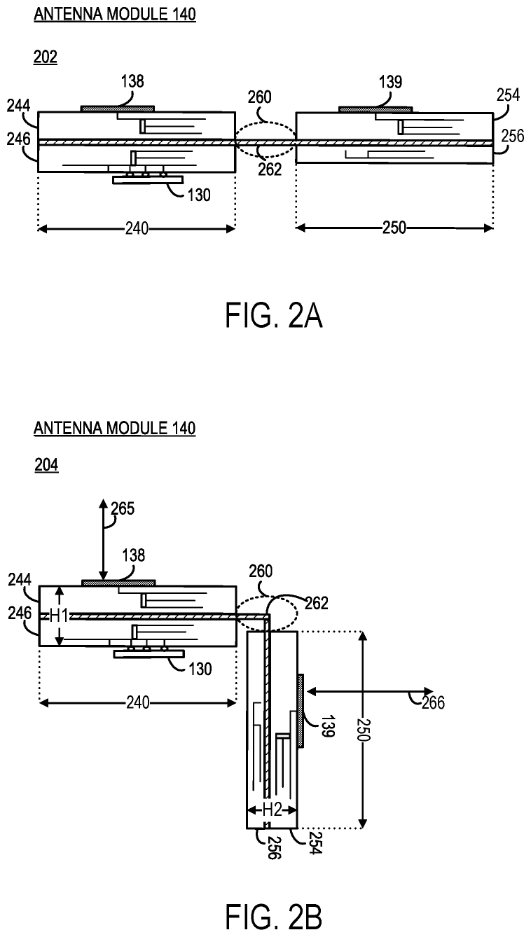

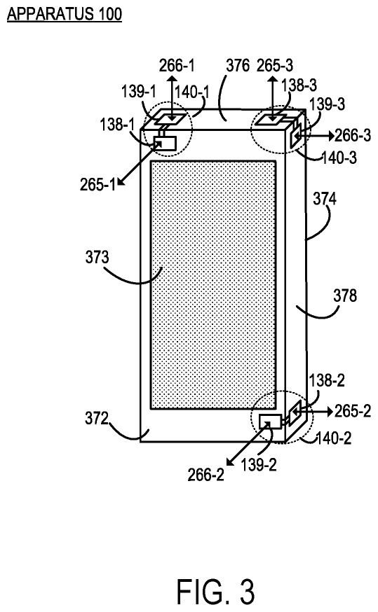

FIG. 2A illustrates physical representation of the antenna module 140 of FIG. 1 arranged in a first position 202, in accordance with certain aspects of the present disclosure. The antenna module 140 may include a first portion 240, a second portion 250, and a flexible portion 260. In some examples, the first portion 240 and/or the second portion 250 are rigid portions. The flexible portion 260 may physically connect the first portion 240 and the second portion 250.

The antenna module 140 may include multiple layers. For example, the first portion 240 may include multiple signal routing layers 244 and 246 (each of which may include multiple layers of conductive routings). The second portion 250 may include multiple signal routing layers 254 and 256 (each of which may include multiple layers of conductive routings). Examples of the signal routing layers 244, 246, 254, and 256 may include multi layered printed circuit boards (PCBs). The first portion 240, the second portion 250, and the flexible portion 260 may further include a flexible layer 262. The flexible layer 262 may be, for example, a resin layer that is bendable.

In some examples, the signal routing layers 244, 246, 254, and 256, e.g., PCBs, provide rigidity to the first portion 240 and the second portion 250. In some examples, the flexible portion 260 includes flexible layer 262 and no PCBs such that the flexible portion 260 remains bendable. The antenna module 140, including the first portion 240, the second portion 250, and the flexible portion 260, may be an integrated structure. For example, the flexible portion 260 might not be separately structure attached to the first portion 240 or the second portion 250. The flexible portion 260 may be an integral part of the first portion 240 and the second portion 250, and of the antenna module 140.

The first antenna 138 (FIG. 1) may be on (e.g., physically on) the first portion 240. For example, the first antenna 138 may be physically attached to the signal routing layers 244 of the first portion 240. The second antenna 139 (FIG. 1) may be on (e.g., physically on) the second portion 250. For example, the second antenna 139 may be physically attached to the signal routing layers 254 of the second portion 250. At least one RFIC 130 (FIG. 1) may be on, e.g., physically on, the first portion 240. For example, the at least one RFIC 130 may be physically attached to the signal routing layers 246 of the first portion 240. As presented with FIG. 1, the RFIC 130 may include one of a transceiver 120, a power management integrated circuit 125, or a radio frequency front-end 131 (FIG. 1).

In some examples, the first antenna 138 and the second antenna 139 (via the flexible portion 260) may share the RFIC 130 for RF signal transmission or reception. For example, the first antenna 138 and the second antenna 139 may be configured to transmit RF signals from the RFIC 130 (e.g., from the baseband processor 114 via the RFIC 130; see FIG. 1). In some examples, the first antenna 138 and the second antenna 139 may be configured to receive RF signals and to provide the RF signals to the RFIC 130 (e.g., to the baseband processor 114 via the RFIC 130; see FIG. 1). In addition, a passive component (e.g., inductor or capacitor; not shown) may be on the first portion (e.g., physically on the signal routing layers 246 of the first portion 240). The passive component may operate with the RFIC 130 to facilitate RF communication described above.

Conductive routings (not shown) may be provided on the flexible layer 262 to couple the first portion 240 and the second portion 250 by convening electrical or RF signals. In such fashion, the baseband processor 114 may facilitate, via the RFIC 130, the first antenna 138 and the second antenna 139 to transmit and/or to receive same RF signaling. In some examples, the baseband processor 114 may facilitate, via the RFIC 130, the first antenna 138 and the second antenna 139 to transmit and/or to receive different same RF signaling. Thus, the first antenna 138 and the second antenna 139 may operate as one antenna system under certain conditions (e.g., to receive weak RF signals) and operate as different antenna systems to other conditions (e.g., to increase throughput).

FIG. 2B illustrates physical representation of the antenna module 140 of FIG. 1 arranged in a second position 204, in accordance with certain aspects of the present disclosure. The flexible portion 260 may be arrangeable such that the first antenna 138 and the second antenna 139 are oriented to receive RF signals from different directions or to transmit RF signals to different directions (the second position 204). Under certain conditions, millimeter signaling in 5G wireless communication may bounce or reflect off surfaces such as walls or doors. Accordingly, the first antenna 138 and the second antenna 139 may be oriented to receive or to transmit RF signals in different directions, the different directions being sufficient to improve coverage of radio signal transmission and reception to satisfy demands for 5G signaling.

In FIG. 2B, the flexible layer 262 in the flexible 260 are bent to approximately 90 degrees. The antenna module 140 may be affixed to a motherboard module (not shown) of the apparatus 100 of FIG. 1 to maintain the second position 204. The first antenna 138 may be oriented to receive or to transmit RF signals 265 in first direction. The second antenna 139 may be oriented or receive or to transmit RF signals 266 in a second direction. The first direction and the second direction may be orthogonal. In some examples, the first antenna 138 and the second antenna 139 may be oriented in different directions and may be orthogonal. In some examples, the first antenna 138 and the second antenna 139 may be oriented to sufficiently receive or transmit RF signals from orthogonal directions.

In some examples, the first portion 240 and the second portion 250 may be of different heights. For example, the first portion 240 and the second portion 250 may be of different numbers of layers. The signal routing layers 256 of the second portion 250 may have fewer layers of conductive routings than that of the signal routing layers 246 of the first portion 240. Accordingly, a height H2 of the second portion 250 may be lower than a height H1 of the first portion 240 to, for example, accommodate an additional height of the at least one RFIC 130 or a shape of the motherboard module upon which the antenna module 140 is affixed. As a result, the different heights or numbers of layers may allow for small radius of banding (e.g., of the flexible portion 260) so to minimize a volume occupied by the antenna module 140.

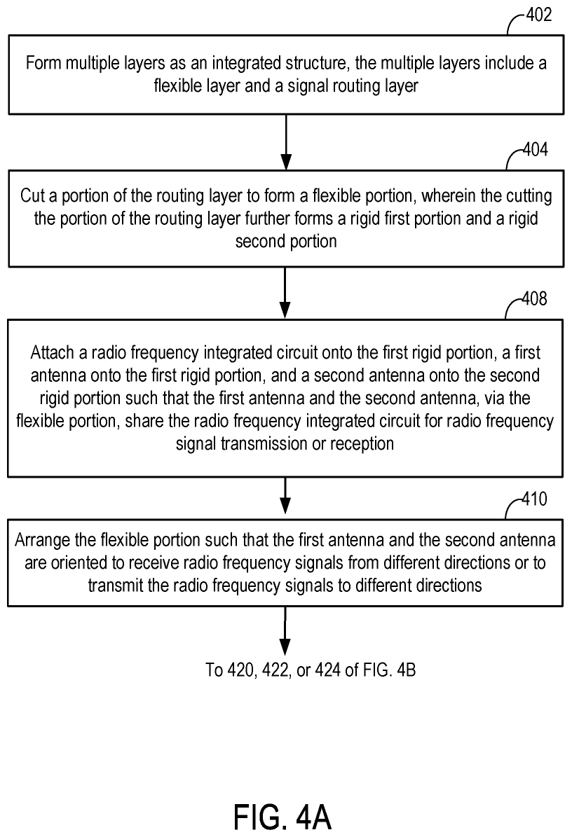

FIG. 3 illustrates a perspective view of the apparatus 100 incorporating the antenna module 140 of FIG. 1, in accordance with certain aspects of the present disclosure. The apparatus 100 may be, for example, a cell phone. The apparatus 100 may include a front side 372 and a back side 374 opposing the front side 372. For example, the back side 374 may be parallel with the front side 372 and face an opposite direction. In some examples, the front side 372 and the back side 374 may be the largest of all surfaces of the apparatus 100, and a display 373 may be incorporated on the front side 372 or the back side 374. The apparatus 100 may further include an edge 376 and a second edge 378 between the front side 372 and the back side 374.

FIG. 3 illustrates, as an example, the apparatus 100 incorporating three instances of the antenna module 140 (referenced as 140-1, 140-2, 140-3). The apparatus 100 may incorporate any or all of the instances in any combination. The antenna module 140-1 (illustrated in perspective view) includes the first antenna 138-1 and the second antenna 139-1. The antenna module 140-2 (illustrated in perspective view) includes the first antenna 138-2 and the second antenna 139-2. The antenna module 140-3 (illustrated in perspective view) includes the first antenna 138-3 and the second antenna 139-3.

Referring to the antenna module 140-1, the first antenna 138-1 is oriented by the flexible portion 260 (FIGS. 2A and 2B) to receive or to transmit radio frequency signals 265-1 in a direction through the front side 372 or the back side 374. The second antenna 139-1 is oriented by the flexible portion 260 to receive or to transmit radio frequency signals 266-1 in a direction through the edge 376. In some examples, the first antenna 138-1 and the second antenna 139-1 may be oriented orthogonally by the flexible portion 260 and therefore, oriented to receive or to transmit the radio frequency signals 265-1 and 266-1 from or to orthogonal directions. In some examples, the direction through the front side 372 or the back side 374 and the direction through the edge 376 may be orthogonal.

Referring to the antenna module 140-2, the first antenna 138-2 is oriented by the flexible portion 260 to receive or to transmit radio frequency signals 265-2 in a direction through the second edge 378. The second antenna 139-2 is oriented by the flexible portion 260 to receive or to transmit radio frequency signals 266-2 in a direction through the front side 372 or the back side 374. In some examples, the first antenna 138-2 and the second antenna 139-2 may be oriented orthogonally by the flexible portion 260 and therefore, oriented to receive or to transmit the radio frequency signals 265-2 and 266-2 from or to orthogonal directions. In some examples, the direction through the second edge 378 and the direction through the front side 372 or the back side 374 may be orthogonal.

Referring to the antenna module 140-3, the first antenna 138-3 is oriented by the flexible portion 260 to receive or to transmit radio frequency signals 265-3 in a direction through the edge 376. The second antenna 139-3 is oriented by the flexible portion 260 to receive or to transmit radio frequency signals 266-3 in a direction through the second edge 378. In some examples, the first antenna 138-3 and the second antenna 139-3 may be oriented orthogonally by the flexible portion 260 and therefore, oriented to receive or to transmit the radio frequency signals 265-3 and 266-3 from or to orthogonal directions. In some examples, the direction through the edge 376 and the direction through the second edge 378 may be orthogonal.

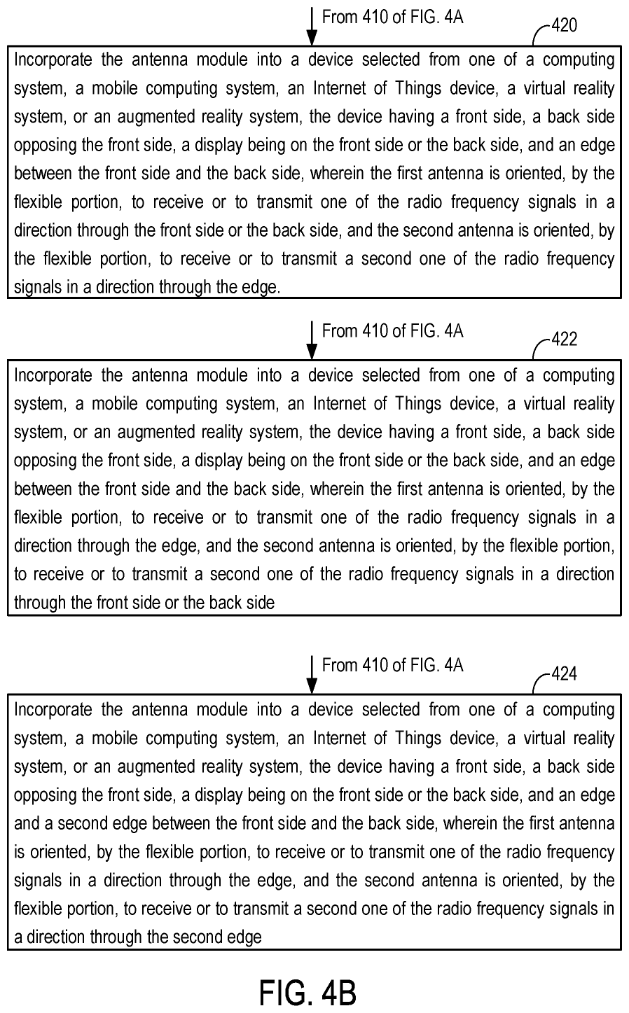

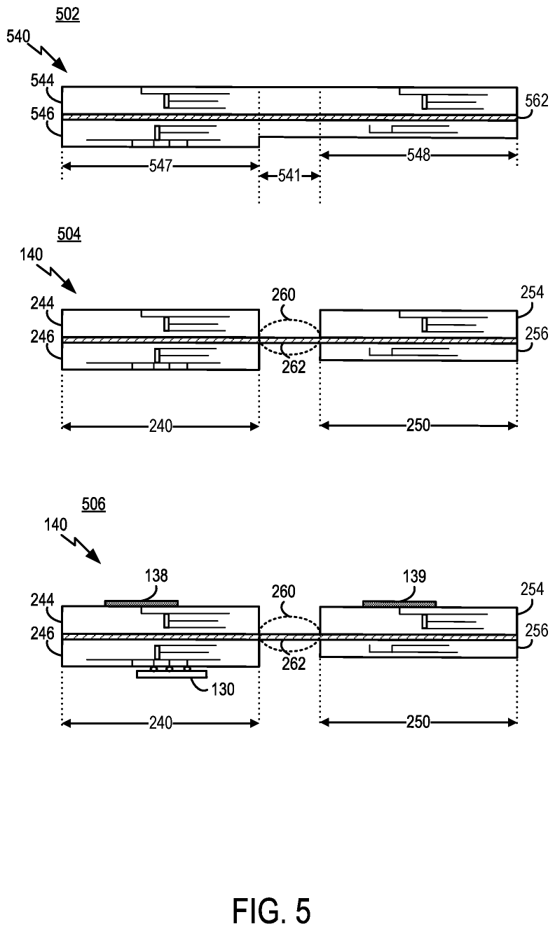

FIGS. 4A and 4B illustrate a method to manufacture the apparatus 100 incorporating the antenna module 140 of FIG. 1, in accordance with certain aspects of the present disclosure. Operations shown may not be indicative of ordering of the operations. Operations are presented with FIG. 5. FIG. 5 illustrates stages of the method of FIGS. 4A and 4B, in accordance with certain aspects of the present disclosure.

At 402, multiple layers are formed as an integrated structure, the multiple layers including a flexible layer and a signal routing layer. Referring to FIG. 5 at 502, an integrated structure 540 is formed with signal routing layers 544 and 546 and a flexible layer 562. The signal routing layers 544 and 546 may be instances of the signal routing layers 244 and 246 of FIGS. 2A and 2B. The flexible layer 562 may be an instance of the flexible layer 262 of FIGS. 2A and 2B. The integrated structure 540 may be formed by, for example, deposition and/or laminating the signal routing layers 544 and 546 and the flexible layer 562.

The flexible layer 562 may be, for example, resin. Each of the signal routing layers 544 and 546 may include multiple layers of conductive routings. The signal routing layers 544 and 546 may be rigid. The signal routing layers 546 may include a portion 547 and a portion 548. The portions 547 and 548 may be of different heights or include different layers of conductive routings. The integrated structure 540 includes a portion 541 to be cut out to form a flexible portion.

At 404, a portion of the routing layer is cut to form a flexible portion. The cutting of the portion of the routing layer further forms a rigid first portion or a rigid second portion. Referring to FIG. 5 at 504, portion 541 is cut to form a part of the antenna module 140 (FIGS. 2A and 2B), including a first portion 240, a flexible portion 260, and a second portion 250. The first portion 240 and the second portion 250 are rigid portions. In some examples, only the signal routing layers 546 at a bottom or a top of the first portion 240 are cut. Some examples, the signal routing layers 546 at both the bottom and the top of the first portion 240 are cut.

The portion 547 at 502 becomes the signal routing layers 246 of the first portion 240, and the portion 548 at 502 becomes the signal routing layers 256 of the second portion 250. Thus, because the portions 547 and 548 are of different heights or different numbers of conductive routing layers, the first portion 240 and the second portion 250 may be of different heights or different numbers of conductive routing layers.

At 408, a radio frequency integrated circuit is attached onto the first rigid portion, a first antenna onto the first rigid portion, and a second antenna onto the second rigid portion. The first antenna and the second antenna, via the flexible portion, share the radio frequency integrated circuit for radio frequency signal transmission or reception. Referring to FIG. 5 at 506, radio frequency integrated circuit 130 is attached (e.g., physically attached) to the signal routing layers 246 of the first portion 240. The radio frequency integrated circuit 130 may include one or more of a transceiver 120, a power management integrated circuit (PMIC) 125, an RF front-end 131, and/or an envelope-tracking circuit (not shown), etc.

The first antenna 138 is attached (e.g., physically attached) onto the signal routing layers 244 of the first portion 240. The second antenna 139 is attached (e.g., physically attached) to the signal routing layers 254 of the second portion 250. The attachments of the radio frequency integrated circuit 130, the first antenna 138, and the second antenna 139 are such that the first antenna 138 and the second antenna 139, via the flexible portion 260, share the radio frequency integrated circuit 130 for radio frequency signal transmission or reception. For example, the first antenna 138 and the second antenna 139 are coupled to share electrical signals and/or radio frequency signals with the radio frequency integrated circuit 130 via the flexible portion 260 (e.g., via routing layers (not shown) thereon).

At 410, the flexible portion is arranged such that the first antenna and the second antenna are oriented to receive radio frequency signals from different directions or to transmit the radio frequency signals to different directions. For example, referring to FIG. 2B, the flexible portion 260 (e.g., the flexible layer 262) is arranged such that the first antenna 138 and the second antenna 139 are oriented to receive or to transmit radio frequency signals 265, 266 from or to different directions. In some examples, the radio frequency signals 265 and 266 are traveling in orthogonal directions.

Referring to FIG. 4B, at 420, the antenna module is incorporated into a device selected from one of a computing system, a mobile computing system, an Internet of Things device, a virtual reality system, or an augmented reality system. The device has a front side; a back side opposing the front side, a display being on the front side or the back side; and an edge between the front side and the back side. The first antenna is oriented, by the flexible portion, to receive or to transmit one of the radio frequency signals in a direction through the front side or the back side. The second antenna is oriented, by the flexible portion, to receive or to transmit a second one of the radio frequency signals in a direction through the edge. Referring to FIG. 3, for example, the antenna module 140-1 is incorporate into the apparatus 100, which may be a mobile communication device. The apparatus 100 includes the front side 372 having the display 373 thereon, the back side 374, the edge 376, and the second edge 378. The edge 376 and the second edge 378 are between the front side 372 and the back side 374.

The first antenna 138-1 is oriented, by the flexible portion 260 of antenna module 140-1, to receive or to transmit the radio frequency signals 265-1 in a direction through the front side 372 (or in some examples, through the back side 374), and the second antenna 139-1 is oriented, by the flexible portion 260 of antenna module 140-1, to receive or to transmit radio frequency signals 266-1 in a direction through the edge 376. In some examples, the directions of the radio frequency signals 265-1 and 266-1 may be orthogonal. In some examples, the radio frequency signals 265-1 and 266-1 may be instances of a same radio frequency signaling or multiple radio frequency signaling. In some examples, the direction through the front side 372 or the back side 374 may be orthogonal to the front side 372 or the back side 374, and the direction through the edge 376 may be orthogonal to the edge 376.

At 422, the antenna module is incorporated into a device selected from one of a computing system, a mobile computing system, an Internet of Things device, a virtual reality system, or an augmented reality system. The device has a front side; a back side opposing the front side, a display being on the front side or the back side; and an edge between the front side and the back side. The first antenna is oriented, by the flexible portion, to receive or to transmit one of the radio frequency signals in a direction through the edge. The second antenna is oriented, by the flexible portion, to receive or to transmit a second one of the radio frequency signals in a direction through the front side or the back side.

Referring to FIG. 3, for example, the antenna module 140-2 is incorporate into the apparatus 100, which may be a mobile communication device. The first antenna 138-2 is oriented, by the flexible portion 260 of antenna module 140-2, to receive or to transmit the radio frequency signals 265-2 in a direction through the second edge 378, and the second antenna 139-2 is oriented, by the flexible portion 260 of antenna module 140-2, to receive or to transmit radio frequency signals 266-2 in a direction through the front side 372 (or in some examples, through the back side 374). In some examples, the directions of the radio frequency signals 265-2 and 266-2 may be orthogonal. In some examples, the radio frequency signals 265-2 and 266-2 may be instances of a same radio frequency signaling or multiple radio frequency signaling. In some examples, the direction through the front side 372 or the back side 774 may be orthogonal to the front side 372 or the back side 374, and the direction through the second edge 378 may be orthogonal to the second edge 378.

At 424, the antenna module is incorporated into a device selected from one of a computing system, a mobile computing system, an Internet of Things device, a virtual reality system, or an augmented reality system. The device has a front side; a back side opposing the front side, a display being on the front side or the back side; and an edge and a second edge between the front side and the back side. The first antenna is oriented, by the flexible portion, to receive or to transmit one of the radio frequency signals in a direction through the edge. The second antenna is oriented, by the flexible portion, to receive or to transmit a second one of the radio frequency signals in a direction through the second edge.

Referring to FIG. 3, for example, the antenna module 140-3 is incorporated into the apparatus 100, which may be a mobile communication device. The first antenna 138-3 is oriented, by the flexible portion 260 of antenna module 140-3, to receive or to transmit the radio frequency signals 265-3 in a direction through the edge 376. The second antenna 139-3 is oriented, by the flexible portion 260 of antenna module 140-3, to receive or to transmit radio frequency signals 266-3 in a direction through the second edge 378. In some examples, the directions of the radio frequency signals 265-3 and 266-3 may be orthogonal. In some examples, the radio frequency signals 265-3 and 266-3 may be instances of a same radio frequency signaling or multiple radio frequency signaling. In some examples, the direction through the edge 376 may be orthogonal to the edge 376, and the direction through the second edge 378 may be orthogonal to the second edge 378.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. An apparatus, comprising:
an antenna module, comprising:
a first portion;
a first antenna on the first portion;
a second portion;
a second antenna on the second portion;
a flexible portion physically connecting the first portion and the second portion, the flexible portion being arrangeable such that the first antenna and the second antenna are oriented to receive radio frequency signals from different directions or to transmit the radio frequency signals to different directions; and
a radio frequency integrated circuit on the first portion, wherein the first antenna and the second antenna, via the flexible portion, share the radio frequency integrated circuit for radio frequency signal transmission or reception.

2. The apparatus of claim 1, wherein the first portion, the second portion, and the flexible portion are an integrated structure.

3. The apparatus of claim 2, wherein the first antenna and the second antenna are oriented orthogonally.

4. The apparatus of claim 2, wherein the first antenna and the second antenna are configured to transmit the radio frequency signals from the radio frequency integrated circuit and configured to receive the radio frequency signals and to provide the radio frequency signals to the radio frequency integrated circuit.

5. The apparatus of claim 2, wherein the radio frequency integrated circuit comprises a transceiver, a power management integrated circuit, or a radio frequency front-end.

6. The apparatus of claim 5, further comprising a passive component on the first portion.

7. The apparatus of claim 5, wherein the first portion and the second portion are rigid and of different heights.

8. The apparatus of claim 5, wherein the first portion and the second portion are of different numbers of layers.

9. The apparatus of claim 5, further comprising a device selected from one of a computing system, a mobile computing system, an Internet of Things device, a virtual reality system, or an augmented reality system, the device incorporating the antenna module and a processor, the processor being coupled to the antenna module to perform wireless communications.

10. The apparatus of claim 9, wherein the device further comprises
a front side;
a back side opposing the front side, a display being on the front side or the back side; and
an edge between the front side and the back side,
wherein the first antenna is oriented, by the flexible portion, to receive or to transmit one of the radio frequency signals in a direction through the front side or the back side, and
the second antenna is oriented, by the flexible portion, to receive or to transmit a second one of the radio frequency signals in a direction through the edge.

11. The apparatus of claim 10, the direction through the front side or the back side being orthogonal to the front side or the back side, and the direction through the edge being orthogonal to the edge.

12. The apparatus of claim 9, wherein the device further comprises
a front side;
a back side opposing the front side, a display being on the front side or the back side; and
an edge between the front side and the back side,
wherein the first antenna is oriented, by the flexible portion, to receive or to transmit one of the radio frequency signals in a direction through the edge, and
the second antenna is oriented, by the flexible portion, to receive or to transmit a second one of the radio frequency signals in a direction through the front side or the back side.

13. The apparatus of claim 12, the direction through the front side or the back side being orthogonal to the front side or the back side, and the direction through the edge being orthogonal to the edge.

14. The apparatus of claim 9, wherein the device further comprises
a front side;
a back side opposing the front side, a display being on the front side or the back side;
an edge and a second edge between the front side and the back side; and
wherein the first antenna is oriented, by the flexible portion, to receive or to transmit one the radio frequency signals in a direction through the edge, and
the second antenna is oriented, by the flexible portion, to receive or to transmit a second one of the radio frequency signals in a direction through the second edge.

15. The apparatus of claim 14, the direction through the edge being orthogonal to the edge, and the direction through the second edge being orthogonal to the second edge.

16. A method to form an apparatus incorporating an antenna module with a flexible portion, comprising:
forming a plurality of layers as an integrated structure, the plurality of layers comprising a flexible layer and a signal routing layer;
cutting a portion of the plurality of layers to form a flexible portion.

17. The method of claim 16, wherein cutting the portion of the plurality of layers further forms a first rigid portion and a second rigid portion.

18. The method of claim 17, wherein the first rigid portion and the second rigid portion are of different heights.

19. The method of claim 17, wherein the first rigid portion and the second rigid portion are of different numbers of layers.

20. The method of claim 17, further comprising:
attaching a radio frequency integrated circuit onto the first rigid portion, a first antenna onto the first rigid portion, and a second antenna onto the second rigid portion such that the first antenna and the second antenna, via the flexible portion, share the radio frequency integrated circuit for radio frequency signal transmission or reception.

21. The method of claim 20, further comprising:
arranging the flexible portion such that the first antenna and the second antenna are oriented to receive radio frequency signals from different directions or to transmit the radio frequency signals to different directions.

22. The method of claim 21, further comprising:
incorporating the antenna module into a device selected from one of a computing system, a mobile computing system, an Internet of Things device, a virtual reality system, or an augmented reality system,
the device having a front side,
a back side opposing the front side, a display being on the front side or the back side, and
an edge between the front side and the back side,
wherein the first antenna is oriented, by the flexible portion, to receive or to transmit one of the radio frequency signals in a direction through the front side or the back side, and
the second antenna is oriented, by the flexible portion, to receive or to transmit a second one of the radio frequency signals in a direction through the edge.

23. The method of claim 22, the direction through the front side or the back side being orthogonal to the front side or the back side, and the direction through the edge being orthogonal to the edge.

24. The method of claim 21, further comprising:
incorporating the antenna module into a device selected from one of a computing system, a mobile computing system, an Internet of Things device, a virtual reality system, or an augmented reality system,
the device having a front side,
a back side opposing the front side, a display being on the front side or the back side, and
an edge between the front side and the back side,
wherein the first antenna is oriented, by the flexible portion, to receive or to transmit one of the radio frequency signals in a direction through the edge, and
the second antenna is oriented, by the flexible portion, to receive or to transmit a second one of the radio frequency signals in a direction through the front side or the back side.

25. The method of claim 24, the direction through the front side or the back side being orthogonal to the front side or the back side, and the direction through the edge being orthogonal to the edge.

26. The method of claim 21, further comprising:
incorporating the antenna module into a device selected from one of a computing system, a mobile computing system, an Internet of Things device, a virtual reality system, or an augmented reality system,
the device having a front side,
a back side opposing the front side, a display being on the front side or the back side, and
an edge and a second edge between the front side and the back side,
wherein the first antenna is oriented, by the flexible portion, to receive or to transmit one of the radio frequency signals in a direction through the edge, and
the second antenna is oriented, by the flexible portion, to receive or to transmit a second one of the radio frequency signals in a direction through the second edge.

27. The method of claim 26, the direction through the edge being orthogonal to the edge, and the direction through the second edge being orthogonal to the second edge.
